(19) United States
(12) Patent Application Publication
(10) Pub. No.: US 2025/0349689 A1
(43) Pub. Date: Nov. 13, 2025

(54) SEMICONDUCTOR DEVICE AND METHOD OF FORMING REDISTRIBUTION STRUCTURES OF CONDUCTIVE ELEMENTS

(71) Applicant: Taiwan Semiconductor Manufacturing Company, Ltd., Hsinchu (TW)

(72) Inventors: Ho Che Yu, Zhubei City (TW); Fong-yuan Chang, Hsinchu County (TW); Ting-Chieh Hsu, Hsinchu County (TW); Chun-Hua Chang, Zhubei City (TW)

(73) Assignee: Taiwan Semiconductor Manufacturing Company, Ltd., Hsinchu (TW)

(21) Appl. No.: 19/280,599

(22) Filed: Jul. 25, 2025

Related U.S. Application Data
(62) Division of application No. 17/835,776, filed on Jun. 8, 2022.

(51) Int. Cl. H01L 23/498; H01L 23/48

(52) U.S. Cl. CPC H01L 23/49822; H01L 23/481; H01L 23/49827

(57) ABSTRACT

A semiconductor device and method of manufacture in which a first semiconductor die is disposed along a first redistribution structure, and a second redistribution structure is disposed along an opposite side of the first redistribution structure. A third redistribution structure may be disposed along an opposite surface of the semiconductor die as the first redistribution structure. Through via structures pass through at least the first redistribution structure to connect at least one of the redistribution structures to an active surface of the semiconductor die.

### CROSS-REFERENCE TO RELATED APPLICATIONS

This application is a divisional of U.S. patent application Ser. No. 17/835,776, filed Jun. 8, 2022, which is incorporated herein by reference in its entirety for all purposes.

### BACKGROUND

Semiconductor devices are ubiquitous in several applications and devices throughout most industries. For example, consumer electronics devices such as personal computers, cellular telephones, and wearable devices may contain several semiconductor devices. Similarly, industrial products such as test instruments, vehicles, and automation systems frequently comprise a large number of semiconductor devices. As semiconductor manufacturing improves, semiconductors continue to be used in new applications which, in turn, leads to increased demands of semiconductor performance, cost, reliability, etc.

These semiconductor devices are fabricated by a combination of front end of line (“FEOL”) processes, which manufacture semiconductor (e.g., silicon) dies, and back end of line (“BEOL”) processes, which package one or more of these dies into a semiconductor device that can interface with other devices. For example, the package may combine a plurality of semiconductor dies and can be configured to be attached to a printed circuit board or other interconnected substrate, which may, in turn, allow the plurality of semiconductor dies of the semiconductor device to interface with additional semiconductor devices or other devices, power sources, communication channels, etc.

Physical demands for device miniaturization, increasing connectedness, and power efficiency are driving increases to semiconductor device density. Some of this increase in density can be attributed to improvements in the FEOL processes, including die miniaturization. Modern packaging technologies (e.g., package on package (POP), Fan-Out packaging (FO), etc.) are also driving miniaturization, intercommunication, power savings and other improvements. The one or more dies of these modern packages may be interconnected or connected to package inputs and/or outputs (I/O) by bond wires, through-silicon vias (TSVs), metallization layers/vias coupled to the silicon dies, etc. While such connections use sophisticated techniques, further improvements are needed to advance the state of the art.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1a, 1b, 1c, 1d, 1e, 1f, 1g, and 1h illustrate cross sectional views of intermediate stages in the formation of a semiconductor device, in accordance with some embodiments.

FIG. 2 illustrates a cross sectional view of a redistribution layer of a semiconductor device, in accordance with some embodiments.

FIGS. 3a, 3b, and 3c illustrate cross sectional views of intermediate stages in the formation of another semiconductor device, in accordance with some embodiments.

FIG. 4 includes a flowchart of an example method of fabricating a semiconductor device, in accordance with some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over, or on a second feature in the description that follows may include embodiments in which the first and second features are formed in direct contact and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” “top,” “bottom” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Selecting redistribution structure geometry to minimize the resistance of various current paths of a semiconductor device, such as relatively low z-height of layers of redistribution structures carrying vertical currents, and relatively high z-heights of structures carrying lateral currents may improve a PDN of a semiconductor device, minimize thermal cross-talk, and improve signal integrity. Further, because certain semiconductor dies (also referred to as chips herein) may operate more efficiently at lower temperatures, greater efficiencies can be realized than would be predicted from resistive considerations alone. For example, mitigating 1 watt of heat may improve total package power by 2 watts or more. Moreover, by using TIVs rather than TSVs in certain semiconductor dies, the thermal mass of those dies may increase. Because many modern semiconductor devices frequently undergo bursty (i.e., episodic) operation, an increased thermal mass may improve device performance for a particular duration of time (e.g., until the die becomes thermally saturated, or a power limit is reached).

A redistribution structure comprises electrically connected conductive pads configured to redistribute connections (e.g., thermal, power, ground, signal, clock, etc.) within a semiconductor device, such as within or along a single layer of a semiconductor device comprising multiple layers. The electrical connections between one or more pads enable connections between a plurality of layers of an electrical device. For example, if a semiconductor die is disposed above a VCC input of a package, a redistribution structure may comprise a first electrical pad electrically connected to the VCC input of the package. In some packages (e.g., a high power package), a plurality of similar (e.g., VCC or VSS) inputs may be required, and the electrical tracks and pads may connect to at least some of the plurality of these pads. For example, a track may connect every VSS input. Alternatively, a track may connect only some of a plurality of similar inputs. For example in an embodiment, one track connects to a portion the available VCC inputs to form a subnet, VCC_1. Another track connects the remaining portion of the VCC inputs to form a separate subnet, VCC_2, which may, advantageously, minimize interference between a plurality of devices which require electrical connection to VCC. An electrically conductive track (e.g., comprising a metal such as copper, aluminum, tungsten, nickel, gold, or alloys thereof) can be electrically connected to a second conductive pad at a location, such as a location which is not disposed below a semiconductor device, to enable the device to electrically connect vertically (e.g., upwardly or downwardly) to another layer in the semiconductor device without a connection to a semiconductor die, and without passing through the semiconductor die (e.g., by the use of a through-silicon via (TSV)). For example, a through via structure (sometimes referred to as a Through-Interlayer-Via or Through-InFO-Via (TIV)), traverses vertically through the semiconductor device, without passing through a semiconductor die. One skilled in the art will understand that various implementations have various benefits and detriments.

In an embodiment, the conductive track electrically connects to a third electrical pad, a fourth electrical pad, and so on. Each electrical pad is positioned to enable one or more connections. For example, the third electrical pad is placed under a semiconductor die, to enable the connection to the semiconductor die, which may be direct or indirect (e.g., through in intermediate metallization layer), and the fourth electrical pad is placed under an integrated voltage regulator (IVR), to thermally and electrically connect to the IVR. Some semiconductor devices may comprise a plurality of redistribution structures, each of which is disposed within or along a distinct layer of the semiconductor device. In order to protect against unintended connections and signal integrity issues, the redistribution structures comprise an insulator along one or more surfaces thereof, such as a polymer or an oxide to electrically isolate various conductive elements thereof.

A desired thickness of the various conductive elements of a redistribution structure, such as the pad and track, vary, and thus the thickness of redistribution structures vary. For example, a relatively thick track and electrical pad carrying a system VSS may be desirable to minimize resistance. Another relatively thin track and electrical pad may be desirable, for example, to maintain a characteristic impedance of a signal, minimize the z-height of a semiconductor device, etc. In one embodiment, in order to simplify the manufacturing of a semiconductor device, each redistribution structure is composed of a plurality of elements of similar thickness. For example, all of the tracks of a semiconductor device are of a thickness 0.8T, where T represents the thickness of the overall redistribution structure. Electrical pads and/or insulating layer(s) of the redistribution structure are of a thickness 0.1T, such that a redistribution track disposed between two electrical pads or insulating layers may span the total thickness of the redistribution structure, which may enable cascading connections between a plurality of interconnected redistribution structures. The particular numbers used to describe this embodiment is not intended to be limiting, and is merely intended to illustrate that the redistribution structure comprises conductive elements, and may also comprise one or more insulating layers. An alternative embodiment is constructed with conductive elements (e.g., tracks) of 0.2T thickness, and two insulating layers of 0.4T each (or a single insulating layer of 0.8T).

Some embodiments contain redistribution structures comprising conductive elements such as tracks of multiple thicknesses. As used herein, the thickness of a conductive element of a redistribution structure refers to at least 51% of the conductive elements. For example, a redistribution structure comprising 40% of PDN tracks with a thickness of 3 μm, 15% electrical pads overlaid on the track with a total thickness of 4 μm, and 45% guard traces with a thickness of 2 μm is referred to as at least 3 μm thick.

Alternatively or in addition to electrical pads formed over tracks, TIV's, TSV's etc. may couple to the track directly or in combination with solder, flux, etc. In such embodiments, the area of the track which is configured to connect to the TSV's, TIV's, etc. is referred to as an electrical pad. In some semiconductor devices, including those comprising semiconductor dies between redistribution structures, such as an Integrated Fan-Out (InFO) package, two non-adjacent layers may be connected by the use of bond wires, solder bumps, TSV's, TIVs, etc., any of which may be connected directly to a track of a redistribution structure, through an intermediate electrical pad, etc. In some embodiments, the use of TIV's instead of (or in addition to) TSV's may minimize silicon processing steps, maximize signal integrity and otherwise advantage the semiconductor device.

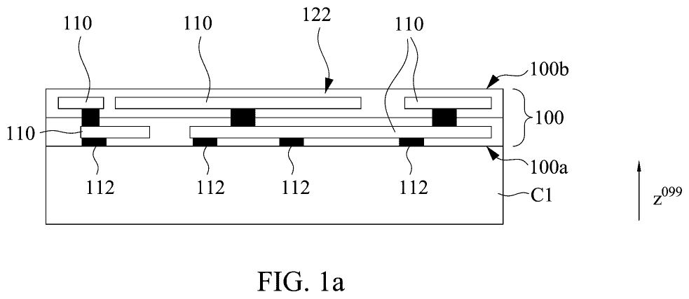

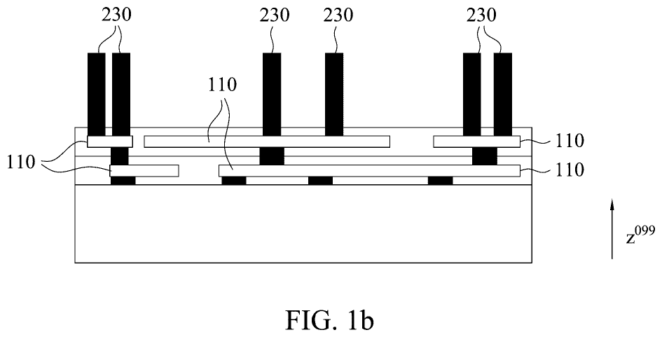

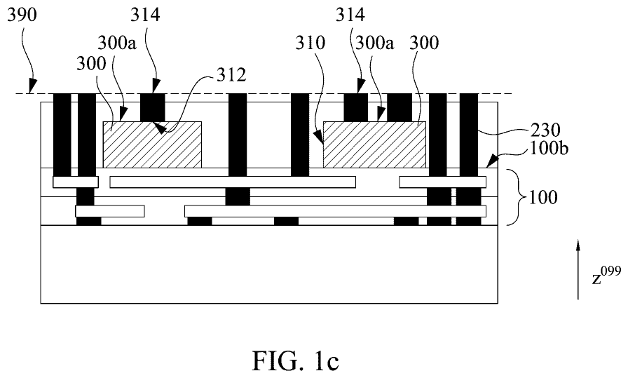

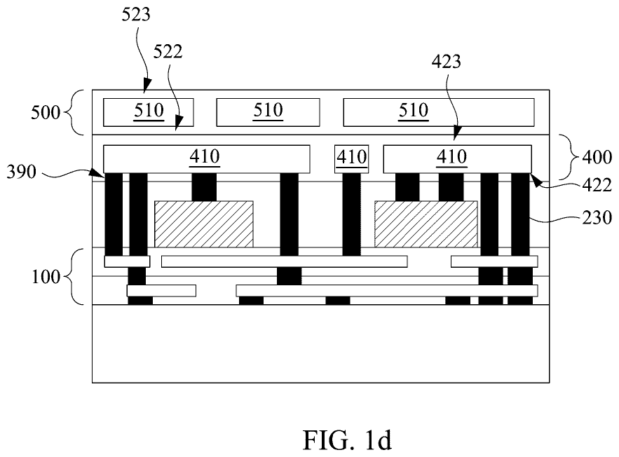

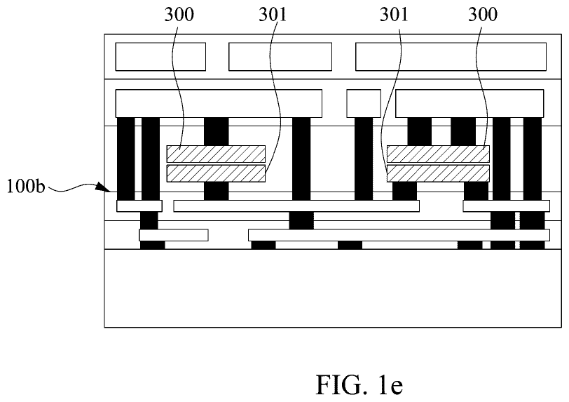

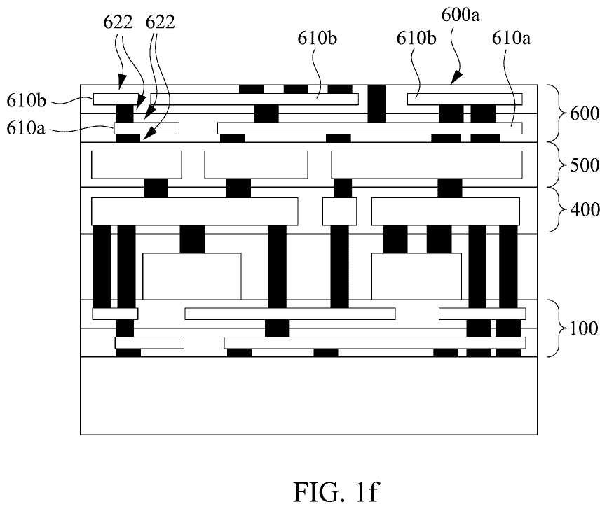

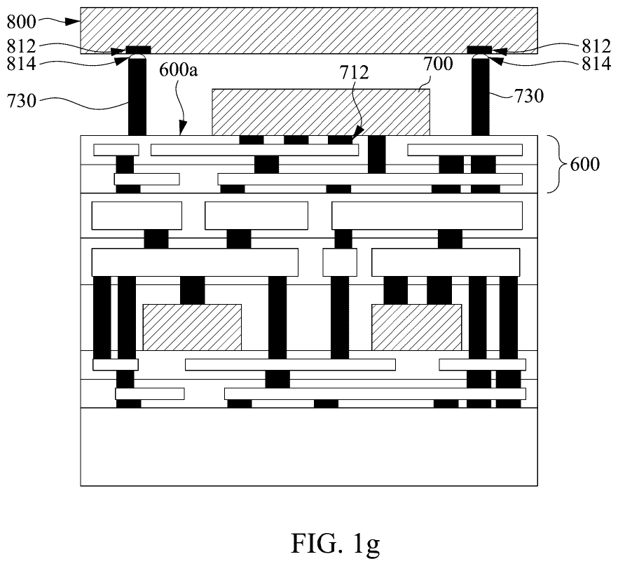

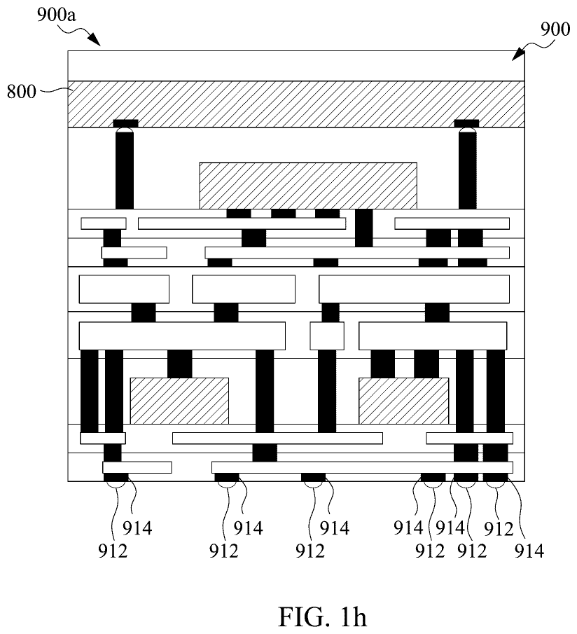

FIGS. 1a through 1h illustrate cross sectional views of intermediate stages in the formation of a semiconductor device, in accordance with some embodiments. Referring to FIG. 1a, a carrier substrate C1 is provided. The carrier substrate C1 may be glass, ceramic, a polymer based material, or a combination of materials. For example, a de-bonding layer such as a light-to-heat conversion release layer may be deposited over a Borosilicate glass body, which may, advantageously, enable the carrier substrate C1 to be removed from temporarily coupled layers while minimizing thermal expansion and contractions during subsequent processing steps. A first redistribution structure 100, comprising a first surface 100a and a second surface 100b opposite the first surface 100a is formed over the carrier substrate C1, with the first surface 100a of the first redistribution structure 100 facing the carrier substrate C1, in a direction termed as “downward” and thus the second surface 100b of the first redistribution structure 100 faces “upwards.” A z-axis 099 indicates this upward direction, as opposed to the two lateral planes (e.g., the leftward and rightward plane, and the backward and forward plane).

Some embodiments may connect a plurality of electrical pads 112 to a plurality of terminals. In an embodiment, at least one of a plurality of electrical pads 112 is disposed on the first surface 100a of the redistribution structure and configured for connection to BGA balls (e.g., to fan out connections to couple the semiconductor device to a PCB), and at least one of the plurality of electrical pads 112 is configured to connect to a solder bump (e.g., to connect to an IPD on a first surface 100a of the redistribution structure), further, at least one of the electrical pads may be connected to metallization layers disposed along the second surface 100b of the redistribution structure, (e.g., to connect to a silicon die), or to other conductive elements of the semiconductor device. The first conductive elements 110 comprise conductive material such as copper, nickel, titanium, a combination thereof, or the like.

The first redistribution structure 100 may comprise a plurality of first conductive elements 110. For example, conductive elements comprising electrical pads 112 which are configured to connect to conductive terminals. In one embodiment, the electrical pads 112 couple directly to solder balls, ball grid array (BGA) balls, controlled collapse chips connections (C4), vias, etc. Alternatively or in addition to a direct connection, the electrical pads may be connected using solder flux, or an intermediate conductive element such as an under-ball metallurgy pattern (UBM). At least one side of the redistribution structure comprises or is overlaid with a first insulating layer 122. The first insulating layer 122, is composed of one or more materials selected according to their insulative and dielectric properties. For example, the insulating material may comprise a polymer such as polybenzoxazole (PBO), polyimide, BCB, or the like; a nitride such as silicon nitride or the like; an oxide such as silicon oxide, PhosphoSilicate Glass (PSG), BoroSilicate Glass (BSG), Boron-doped PhosphoSilicate Glass (BPSG), or the like. The first insulating layer 122 may be formed by molding, spin coating, deposition, CVD, PVD, or other processes known to those skilled in the art.

In some embodiments, the first redistribution structure 100 may comprise additional layers. For example, some embodiments comprise additional alternating layers of conductive elements 110 and insulating layers 122. For example, a ground or power plane may thereby be created, which may, advantageously, improve power and signal integrity, and simplify routing of signals such as data and power. In some embodiments, the thickness of the conductive elements 110 of each layer are similar. For example, a thickness of about 2-5 μm may be used for the first conductive elements 110.

The first insulating layer 122 may be selectively removed (e.g., via a patterning process using a photoresist, by mechanical drilling, laser ablation, etc.) to form a plurality of openings exposing the first conductive elements 110 of the first redistribution structure. At least some of these exposed conductive elements 110 are configured for electrical connection (i.e., are electrical pads 112). In some embodiments, the electrical pads 112 may be populated (i.e., joined to another conductive portion of the semiconductor device) prior to overlaying the insulating layer 122, which may, beneficially, avoid additional process steps.

As illustrated in FIG. 1b, a plurality of first TIVs 230 are electrically connected to the first conductive elements 110 of the first redistribution structure 100. In some embodiments, the TIVs (e.g., the first TIVs 230) may be prefabricated, and placed into contact with the electrical pads 112 of the first redistribution structure 100. In addition or instead of placed TIVs, the first TIVs 230 may be formed/grown in situ. For example, a seed layer (e.g., a titanium/copper composite layer) may be placed over the electrical pads. A plating process may then deposit a conductive material (e.g., copper, gold, aluminum, etc.) over the seed layer to form the TIV. If depositing the seed layer also covers undesired locations, such as the insulating layer, both layers may be covered with a photoresist, selectively masked, and exposed to a light, such that the seed layer is only exposed in desired locations, such as the electrical pads. One skilled in the art will understand that similar outcomes can be achieved with negative photoresists, in which case the masking pattern would be reversed.

Referring now to FIG. 1c, a first plurality of semiconductor dies 300 are placed along the second surface 100b of the first redistribution structure 100 (i.e., upwards from the first redistribution structure 100). The first plurality of dies 300 may comprise processing functions, I/O functions, memory, R/F and analog processing functions such as filtering, or any other function. In some embodiments, the plurality of dies may include relatively high power and high I/O functions, since the dies are placed relatively close to a downward facing side of the semiconductor device, which may, advantageously, minimize resistive power losses, minimize signal routing distances and complexity, etc. Other configurations have competing benefits. For example, including relatively high power devices more upwardly in a device may lower thermal resistance if the device is intended for operation in conjunction with an upper heatsink, and may minimize resistive losses between the die and passive PDN devices disposed along an upper surface of the semiconductor device.

The plurality of semiconductor dies 300 may be silicon or another semiconductor (e.g., germanium, gallium-arsenide, etc.). Each of the plurality of dies 300 may be configured with at least one active surface 300a. The depicted active surface 300a faces upward, towards a second redistribution structure 400, in order to interface with low resistance conductive elements of the second redistribution structure 410 as discussed, infra. In alternate embodiments, a die is placed with an active surface facing in a downwards direction (e.g., as a flip-chip) which may enable a more direct path to signals, PDN, etc, such as through C4 connections.

Minimally, each of the plurality of dies 300 contains a semiconductor substrate 310 having an active surface 300a. They may also comprise one or more additional elements, such as to enable the connection of a die to the rest of the semiconductor device (e.g., mechanically, thermally, electrically, etc.). These additional elements include a plurality of conductive pads 312, a passivation layer, and a post passivation layer, and a protective layer. The semiconductor device may also include die vias 314 to connect various dies to the various redistribution structures, along the z-axis 099 (i.e., upward or downward, depending on the orientation of the plurality of semiconductor dies 300). If a semiconductor die does not include certain features (e.g., a protective layer, die vias 314, etc.) those features may be formed following placement of the die (e.g., along the surface of the die or along the entire surface of the semiconductor device). The semiconductor substrate may comprise at least one active surface 300a having active circuits (e.g., transistors and antennae), and/or passive circuits (e.g., capacitors and filters) thereupon. In some embodiments, the conductive pads 312 of the dies 300 are disposed over the semiconductor substrate, and may couple to one or more circuits of the active surface 300a (e.g., clocks, I/O, PDN, etc.) The conductive pads may be aluminum, copper, or other conductive materials, or alloys or other combinations thereof.

The passivation layer may be a silicon oxide layer, a silicon nitride layer, a silicon oxy-nitride layer, or a dielectric layer formed by other suitable dielectric materials. The post passivation layer is disposed (e.g., formed) over the passivation layer, and may be a PI layer, PBO layer, or a dielectric formed by another suitable polymer/resin. Each of the passivation layers and post passivation layers may comprise contact openings which may allow conductive elements (e.g., the conductive pads 312 or die vias 314) to pass through the respective layers. The protective layer may comprise any suitable material (e.g., resin, polymer) and may be disposed along (e.g., cover) the post passivation layer, and may contain openings for the conductive elements to pass through. Alternatively, the protective layer (or other layers) may not contain openings as mounted to the first redistribution structure 100, and such openings may be formed, (e.g., by a subtractive photoresist process).

The first plurality of semiconductor dies 300 are attached to the redistribution structure (e.g., to the first insulating layer 122) by a die attach film (DAF; not shown) or otherwise. The die is placed so as to be separated in at least one plane which is perpendicular to the z-axis 099 (i.e., laterally spaced) from the first TIVs 230, which may themselves be grown or placed (e.g., the first TIVs 230 may be grown or placed prior to, contemporaneously with, or subsequent to the die). Once the dies and first TIVs 230 are included in the semiconductor device, an encapsulate may cover the first TIVs 230, die, etc., so as to embed the first TIVs 230 and at least one surface of the dies 300 within the encapsulant. In such an embodiment, it may be necessary to grind the encapsulant to a plane to expose the first TIVs 230, die vias, and any other desired elements, such as by chemical mechanical grinding or planarization (CMG/P) mechanical grinding, etc. Advantageously, such a process may result in the various electrical contacts (e.g., the first TIV's 230, and die vias 314) to be exposed at a similar z-height, (i.e., create the first planarized surface 390) which may aid in further process operations. The encapsulant may be a molding compound such as an under-fill compound, a resin, polymer, or the like. In some embodiments, placing the plurality of dies 300 prior to, contemporaneously with, or subsequent to the first TIVs 230 may minimize process steps. For example, it may be advantageous to form the protective layer of a die as a part of the same process step as the encapsulant over the first TIVs 230. One skilled in the art will recognize that various other such steps may be substituted, combined, merged, or otherwise adapted for a particular embodiment.

Referring now to FIG. 1d, a second redistribution structure 400 is disposed along the first planarized surface 390. This second redistribution structure 400 allows for interconnections between any of the first plurality of semiconductor dies 300, the first TIVs 230, other redistribution structures, etc. A thickness of the second redistribution structure may be determined according to the transmission of data signals, power signals, clocks, etc. For example, where the first plurality of dies comprise relatively high power devices, or devices having tight power conditioning devices requirements such as RF circuits requiring low loss transmission lines, a relatively thick redistribution structure may be selected. For example, the thickness of the conductive elements of the redistribution structure may be at least 10 μm (e.g., the conductive elements may be approximately 10 μm, 20 μm, or 30 μm.)

Referring to FIG. 1e, in an alternative embodiment, an active surface of a plurality of alternative semiconductor dies 301 may face in a downward direction, and face the second surface of the first redistribution structure 100b. The alternate semiconductor dies 301 may be placed instead of or in addition to the plurality of semiconductor dies 300. Advantageously, the inclusion of the alternate semiconductor dies 301 may increase the density and performance of the semiconductor device.

In one example, the first plurality of semiconductor dies 300 are high performance processor dies, and are comprise connections to their active surface 300a (e.g., to power connections, VCC and VSS), which may be upwards facing, as in FIG. 1e. Such dies 300 require high current delivery, particularly instantaneous delivery where power load varies considerably over milliseconds, or even microseconds. Such connections may be to a plurality of terminal pins of the die. For example, a die may comprise more than 10 terminal pins connected to VCC (e.g., 15, 44, or 256 pins). In some embodiments, the terminal pins may independently connect to the conductive elements of the second redistribution structure 410. Alternatively, a plurality of terminal pins may be bridged by metallization layers, vias, etc., thus consolidating the number of connections and simplifying the second redistribution layer.

Certain (e.g., high power) dies require the delivery of power through a low-resistance and low-reactance path. If the first redistribution structure 100 primarily passes this current in an upward or downward direction, minimizing the thickness of this layer also minimizes the distance that the current must travel, and hence minimizes transmission losses (e.g., resistive losses). However, because the first TIVs 230 are laterally spaced from the dies 300, currents may travel laterally (e.g., through the conductive elements of the second redistribution structure 410, bond wires, etc.) Thus, maximizing the thickness of the conductive elements of the second redistribution structure 410 may minimize the resistance and otherwise benefit transmission parameters.

In a disclosed embodiment, the downward facing sides of the conductive elements of the second redistribution structure 410 are disposed along a second insulating layer 422, and the upward facing sides of the conductive elements of the second redistribution structure 410 are disposed along a third insulating layer 423. As depicted, these (and various other) insulating layers also cover the lateral extremes of the conductive elements 410 such that the first conductive elements of the second redistribution structure 410 are enveloped by insulating layers 422. The second (and various other) insulating layer 422 comprises openings to allow TIVs or other vias or electrical pads to pass through the insulating layer 422 and connect (e.g., thermally, electrically, mechanically) various layers of the semiconductor device. In some embodiments, the thickness of the second or third insulating layer may be maximized, which may minimize the capacitance between the conductive elements of the second redistribution structure 400. In some embodiments the thickness of the insulating layer 422 may be minimized, which may enable even thicker conductive elements 410, which may minimize the resistance of certain current paths. Other embodiments may similarly benefit from optimizing the size of the conductive elements of the second redistribution structure 410. For example, a RF amplification circuit may benefit from increased power quality supplied by a lower inductance PDN, while a low power thermally sensitive die, such as a die comprising a cryptographic circuit which generates random numbers may benefit from a thinner conductive elements, which may improve thermal dissipation from the dies 300 (e.g., into a PCB which the semiconductor is connected to).

Increasing the cross sectional area of signal (e.g., PDN) propagation by increasing the thickness of the conductive elements 410 alone may reduce resistance. However, it may be inadequate to optimize a design, or may, under particular circumstances, even have negative consequences (e.g., if the resistance of the conductive elements of the second redistribution structure 410 are substantially lower than the resistance of the first TIVs 230, the discontinuity may result in ringing or other signal integrity concerns, or other concerns such as thermal hotspots on the higher resistance first TIVs 230). Thus a thick second redistribution structure 400 may be used in conjunction with high density first TIVs 230. For example, the diameter of at least some of the first TIVs 230 may exceed the spacing between the first TIVs 230. In another example, the radius of at least some of the first TIVs 230 may exceed the spacing between those first TIVs 230. In one embodiment, the TIV to TIV pitch may be less than 100 μm. The spacing may a minimum distance between the first TIVs 230 in a grid pattern, offset pattern, or otherwise. In addition to providing increased PDN performance, increased numbers of first TIVs 230 may also enable greater I/O which may, for example, allow for the use of High Bandwidth Memory and other improved connectivity options in some embodiments.

An additional set of conductive elements 510, termed the conductive elements of a third redistribution structure 500 may be disposed immediately above the second redistribution structure 400. The third redistribution structure 500 is a similar thickness as the second redistribution structure 400, and is disposed along the upper surface of the second redistribution structure 400. The reference to “a third redistribution structure 500,” rather than “an additional set of conductive elements of the second redistribution structure 400,” is merely one method of describing the structure, and does not denote any structural differences compared to the additional layer(s) of the first redistribution structure. For example, the first and second sets of conductive elements of the first redistribution structure 100 may carry power and ground signals, respectively. The second redistribution structure 400 and the third redistribution structure 500 may also carry power and ground signals. For example, the second redistribution structure 400 may carry VSS, and the second redistribution structure may carry VCC.

It should be noted that the conductive elements of any of the second redistribution structure 400 and the third redistribution structure 500 could also carry various data, clock, or other signals. Indeed, if at least some conductive elements carry ground signals, routing certain signals adjacent to the ground signal may provide similar signal integrity benefits as routing those signals along a ground plane. In other embodiments, power and signal grounds may be isolated and it may be inadvisable to run certain signals near power domain conductive elements.

The third redistribution structure 500 may comprise a fourth insulating layer 522 and fifth insulating layer 523 which envelop a third set of conductive elements 510. In an alternative embodiment (not shown) the third set of conductive elements 510 may be disposed along an upper surface of the third insulating layer 423, and a fourth insulating layer 522 may be disposed along an upper surface of the conductive elements. When, as described above, the second redistribution structure 400 and third redistribution structure 500 carry power and ground, the third redistribution structure 500 may be of a similar thickness as the second redistribution structure 400 (e.g., the metal or otherwise conductive portion of the third redistribution structure 500 is at least 10 μm thick).

Referring to FIG. 1f, a fourth redistribution structure 600 is disposed along an upper surface of the third redistribution structure 500. The fourth redistribution structure 600 may comprise two sets or layers of conductive elements 610a, and 610b. Again, the description of the fourth redistribution structure 600 (rather than, e.g., a fourth and fifth redistribution structure, each having one layer of conductive elements) is not intended to be limiting, and is used merely to more clearly describe the figures presented herewith. As described previously for the various redistribution structures, each set of conductive elements 610 may be enveloped by an insulating layer 622, which may contain openings for vias, bond wires, C4 or other bumps, or otherwise allow for the interconnection of layers. For example, C4 bumps or other electrical pads may be disposed along an upper surface of the fourth redistribution structure 600, which may be configured to receive an additional die 700 or plurality of dies along the upper surface 600a of the fourth redistribution structure 600.

Turning now to FIG. 1g, a plurality of second TIVs 730 are disposed along an upper surface of the fourth redistribution structure 600. As with the first TIVs 230, the second TIVs 730 may be grown, placed, or some combination thereof. The second TIVs 730 are laterally spaced from the additional die 700, and may, in some embodiments, be less dense than the plurality of first TIVs 230. For example, if the additional die 700 is powered from C4 bumps 712 disposed along an upper surface of the fourth redistribution structure 500, and the first TIVs 230 and second TIVs 730 are included in a PDN network, for example to carry power and ground, then the total current passed through the second TIVs 730 may be less than the total current passed through the first TIVs 230. Alternatively or in addition, PDN elements (e.g., bulk capacitance, filters, etc.) may be disposed along an upper surface of the semiconductor device, and thus greater currents may flow through the second TIVs 730.

An upper surface of the second TIVs 730 may be configured to connect to solder bumps 814 or other connectors (e.g., may contain solder balls, flux, etc.), which may enable the second TIVs 730 to connect to a layer disposed above the additional die 700. In one embodiment, a memory device 800 (e.g., SRAM, DRAM, NAND FLASH, etc.) may comprise electrical pads 812 which connect to the second TIVs, 730 such as through the solder bumps 814 described above. In some embodiments, the memory device 800 may be a die, which may be similar to the plurality of dies described above. In other embodiments, the memory device 800 may further comprise a package including a molded package body, solder balls or bumps, electrical pads, etc. In some embodiments, a plurality of devices (e.g., memory devices) may be connected to the second TIVs 730, (e.g., through a substrate).

Turning to FIG. 1h, an encapsulant 900 is formed over the memory device 800. In some embodiments, the additional die 700 and the second TIVs 730 may be also be encapsulated (e.g., in a resin, polymer, etc.) prior to the addition of the memory device 800, or as a part of the same process, which may include an under-fill of the additional die 700. As shown, the memory device 800 may be spaced from the additional die 700, which may, advantageously, reduce electrical noise, thermal leakage between devices, etc. Alternatively, the memory device 800 may be disposed immediately above the additional die 700, which may enable I/O between the additional die 700 and an active surface of the memory device 800, such as directly, through the use of solder balls or other electrical pads, or through TSV's.

Some embodiments, may not include TSVs in the first plurality of semiconductor dies 300, the additional die 700, or both. The inclusion of TSVs may, based on certain manufacturing techniques, require grinding silicon dies to a relatively thin z-height (e.g., about 8-15 μm). Because thin wafers may be disposed along one or more redistribution structures and contain very little thermal mass, these devices may become heated due to heat transfer from momentary currents passing through the elements of the various redistribution structures. Thicker silicon dies may mitigate or avoid such issues. Thus, the thicker dies may offer improved performance such as higher Fmax, and lower power usage. Additionally, thicker dies may benefit from increased manufacturability, reliability, etc. Thus in at least some embodiments, it may be advantageous to use dies without TSVs in at least some dies, and further, to include one or more dies of a thickness greater than 15 μm, for example, dies may be included of a thickness of 20 μm, 100 μm, or 200 μm.

As shown in FIG. 1h, the encapsulant may also comprise the terminus of the device, though the encapsulant may be ground down through chemical, or mechanical processes (e.g., to remove thermal resistance between an the various components of the semiconductor device and an upper surface of the encapsulant 900, and may comprise, in some embodiments, grinding gown to expose a portion of the memory device 800). Alternatively, or in addition, the upper surface of the encapsulant 900 may be interfaced with a heatsink or configured to be configured with a heatsink (e.g., by a soldering process thermally connecting the memory device 800.)

The carrier substrate C1 is removed. In one instance, this may include flipping the semiconductor device between the downward and upward direction, and adhering the surface of the encapsulant 900a to a tape. The carrier substrate may then be removed by any process known in the art, (e.g., with a tape adhesive or shearing force, mechanical or chemical grinding or polishing, by UV light (e.g., laser) irradiation of a de-bonding surface disposed along the second surface of the first redistribution structure 100b, etc.). A plurality of conductive terminals 912 are formed along electrical pads 914 disposed along the first surface 100 of the first redistribution structure 100. In some embodiments, the conductive terminals 912 may be configured to connect to a substrate, such as a PCB. For example, the conductive terminals may be BGA balls, leads such as gull-wind leads, a lead frame, etc.

As noted above, the sequence of the disclosed steps are not intended to be limiting, so certain process steps may be practiced in a sequence which may be different than the sequence disclosed, mutatis mutandis. For example, the conductive terminals 912 may be connected directly to the electrical pads 112 shown in FIG. 1a, alternative electrical pads 914 may be formed, or further electrical pads 914 may be formed over pre-existing electrical pads 112. For example, an electrical pad may be formed as referenced in FIG. 1a, which may be formed over the carrier substrate C1, and a separate electrical pad (e.g., a UBM) may be formed subsequent to the removal of the carrier substrate C1. Similarly, an insulating layer disposed along the first surface 100a of the first redistribution structure 100 may be deposited at an early process operation (e.g., directly over the carrier substrate), or at a subsequent operation which may be after the removal of the carrier substrate, or even after the attachment of the semiconductor device to another substrate such as a PCB (e.g., as an under-fill process). Because the sequence of some steps may be altered, references to first, second, etc. will be understood as merely for the purpose of differentiating between similar items, and not to imply a particular sequence of operations, position, etc.

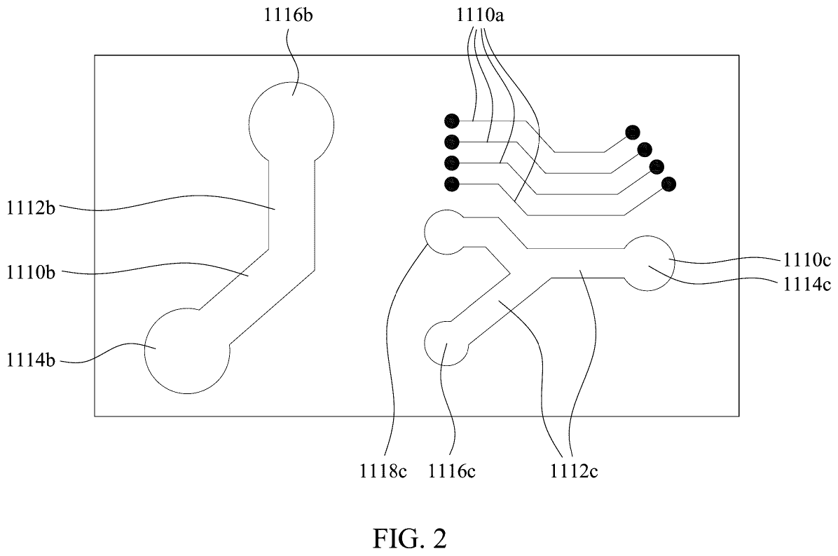

FIG. 2 provides a “downward” view of a redistribution structure of the semiconductor device. The view may represent one embodiment of the conductive elements of the first layer of the first redistribution structure illustrated in FIG. 1a. Conductive elements of the redistribution layer include a plurality of I/O signals 1110a, a first ground pad 1110b, and a second ground pad 1110c. The plurality of I/O signals 1110a travel in both lateral directions of the depicted plane, which may aid in their routing, (e.g., between a silicon die and a BGA ball), and may be configured to carry high speed data signals, such as Peripheral Component Interconnect Express (PCIe) data, clocks, etc. The first ground pad 1110b may comprise a conductive track 1112b, a first electrical pad 1114b, and a second electrical pad 1116b. In an embodiment, the first electrical pad 1114b connects upward to another redistribution structure or layer, and the second electrical pad 1116b connects downward to another layer, such as a silicon die, BGA ball, etc.). The conductive track 1112b joins the two electrical pads to establish an electrical and thermal connection between the various connections. For example, the first ground pad 1110b may extend a ground plane from a PCB connected to a BGA ball to a semiconductor die, through a metallization layer or via. Other embodiments may contain different connections, for example, a ground pad could connect along more than one surface (e.g., could also act as a via). Similarly, the second ground pad 1110c comprises a conductive track 1112c, and a plurality of electrical pads 1114c-18c, and may similarly form various connections with other elements of the semiconductor device. An additional redistribution structure, or layer of the illustrated redistribution structure may contain similar elements which are intended for use with a supply voltage (e.g., VCC) rather than a ground (e.g., VSS). In some embodiments, each elements may connect to one or more semiconductor dies as a component of a PDN network. In some embodiments, the VCC and VSS elements may be geometrically similar, which may, advantageously, minimize signal integrity issues with any nearby signals (e.g., the plurality of I/O signals 1110a). In other embodiments, the VCC and VSS (or other signals of adjoining redistribution structures) may be dissimilar which may, in some embodiments, simplify signal routing.

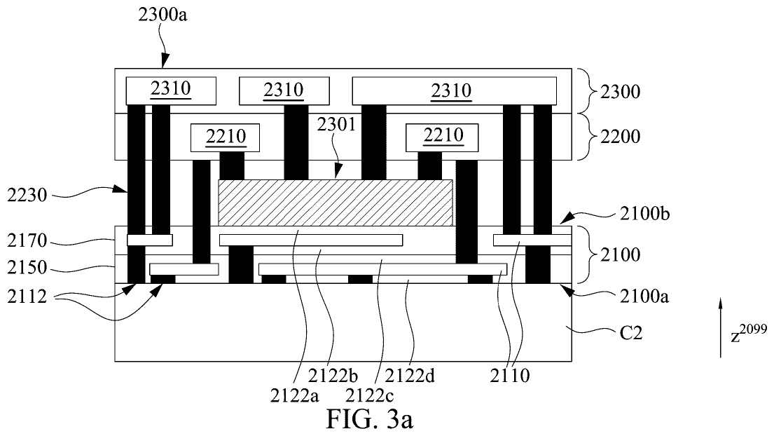

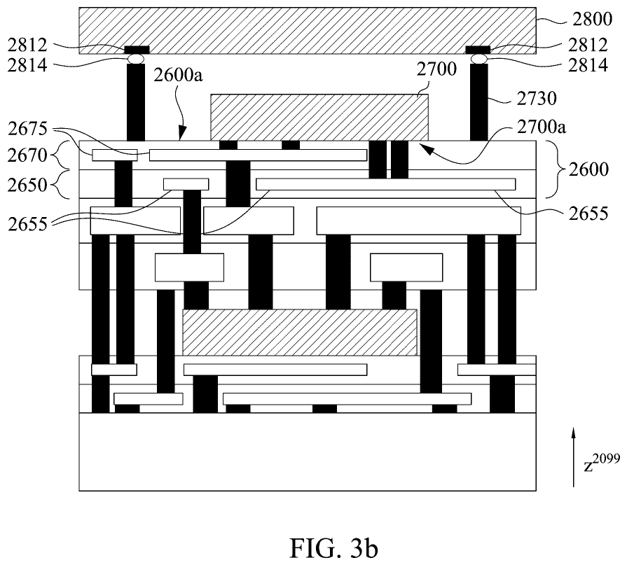

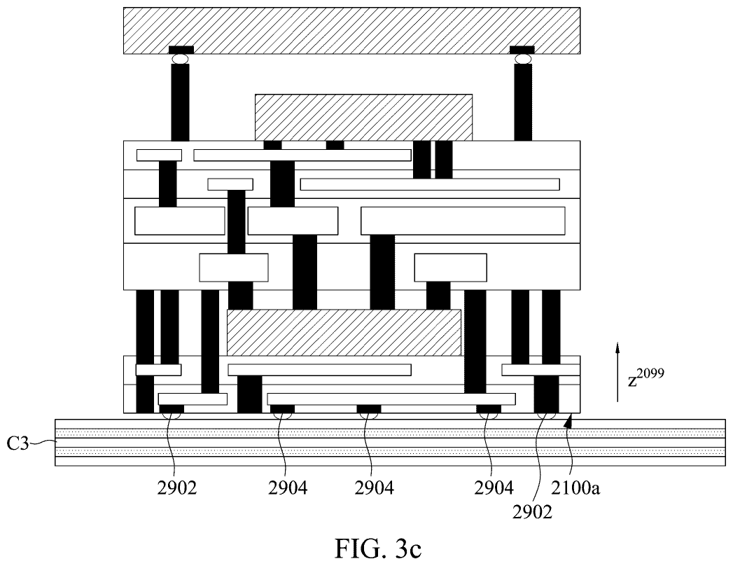

Turning now to FIG. 3a, an additional semiconductor device is disclosed. The semiconductor device is formed along a carrier substrate C2, which may be of similar construction as carrier substrate C1. A first redistribution structure 2100 is formed upon the substrate, having a first layer 2150, which is intended to carry a VSS signal, and a second layer 2170, which is intended to carry a VCC signal. For ease of description, no other signals are shown in the non-limiting embodiment illustrated in FIG. 3a. Each layer of the redistribution structure comprises conductive elements 2110, each of which may be disposed between two insulating layers 2122. In some embodiments, adjacent insulating layers may be manufactured in a single process step, in which a single insulating layer (e.g., a combination of 2122b and 2122c) may be disposed between the conductive elements 2110 of the separate layers of the first redistribution structure 2100. This single insulating layer may be of any thickness, for example, the same thickness as the bottom-most insulating layer 2122d which may harmonize various manufacturing steps, or double the thickness, as depicted, which may better isolate VCC and VSS. Similarly, the thickness of the top-most insulating layer 2122a of the first redistribution structure may be the same thickness as the bottom-most insulating layer 2122d, or any other thickness. The conductive elements may be of any thickness. For example, a thickness in the range of 2-5 μm could be selected.

In some embodiments, electrical contacts may be formed along a bottom-most surface of the first redistribution structure 2100a and may be formed, for example, by depositing a seed layer directly over the carrier substrate C2, and applying metal to the seed layer (e.g., by a plating process such as electro-plating, CVD, PVD, etc.) Alternatively, a metal layer may be placed over the carrier substrate, and a subtractive process may be used to remove the metal except the desired electrical contacts. In some embodiments, additional metal (which may be of the same or different type, alloy, etc.) may be added to the electrical pads 2112 to form vias to reach the conductive elements of the first 2150 and second layers 2170. In some embodiments, (as depicted, to better isolate VSS and VCC to a respective layer of the first redistribution structure 2100) TIVs may be used to travel directly from the first side of the first redistribution structure 2100a to the conductive elements of the second layer of the first redistribution structure 2170). However, in many embodiments, rather than a TIV connecting directly to the second layer of the first redistribution structure 2170, a first via may connect the electrical pad 2112 on the first surface of the first redistribution structure 2100a to a conductive element 2110 of the first redistribution structure 2100 (which may be electrically isolated from other conductive elements 2110 of the first redistribution structure 2100), a second via may connect the conductive element 2110 of the first layer of the redistribution structure 2150 to an additional conductive element 2110 of the second layer of the first redistribution structure 2170, and a third via (e.g., a TIV or other via) may further propagate the connection from the conductive element 2110 of the second layer of the first redistribution structure 2170.

A plurality of first TIVs 2230 may be placed, formed, grown, etc. upon the conductive elements 2110 of the first redistribution structure 2100. Some embodiments may place the TIV's directly upon the tracks of the conductive elements 2110, (which may minimize metal to metal junctions) while other embodiments may include intermediate electrical contacts, vias, etc., which may standardize the z-height (i.e., the length along the z-axis 2099) of the first TIVs. The first TIVs 2230 are laterally spaced from a first semiconductor die 2301 which is placed along the second surface of the first redistribution structure. The first semiconductor die 2301 comprises an active surface which faces in an upward direction (i.e., away from the first redistribution structure). The first semiconductor die 2301 may be encapsulated an any of the encapsulant discussed herein (e.g., resins, polymers, other molding compounds, etc.). In some applications, the encapsulant may extend above the first TIV's 2230 and additional encapsulant may be removed (e.g., by grinding, cutting, or polishing). To connect the active surface to VSS, a second redistribution structure 2200 having a single layer of second conductive elements 2210 disposed between insulating layers is formed above the semiconductor, and VSS may be connected to several die pins disposed along the surface of the first semiconductor dies 300 (e.g., through intermediate vias and metallization layers). A third redistribution structure 2300 having a single layer of second conductive elements 2310 disposed between insulating layers is formed above the second redistribution structure 2200 which may, similarly connect the active surface of the first semiconductor die 2301 to VCC. Because the first semiconductor die 2301 is laterally spaced from each of the first TIVs 2230, VSS and VSS will pass laterally along the length of the conductive elements of the redistribution layer to reach the first semiconductor die 2301. Thus, the conductive elements of each of the second and third redistribution layers may be selected to be greater than 10 μm, and highly conductive. For example, each could be about 30 μm thick and include copper.

Turning to FIG. 3b, a fourth redistribution structure 2600 having an lower layer 2650 comprising fourth conductive elements 2655, intended to carry VSS, and an upper layer 2670 having fifth conductive elements 2675, intended to carry VCC. An active surface of the second semiconductor die 2700a is disposed along a top surface of the fourth redistribution layer 2600a. The second semiconductor die may electrically connect to the lower and upper layer of the fourth redistribution structure in any manner known to those in the art (e.g., by vias and C4 bumps joining the conductive elements 2655, 2675 to metallization layers of the semiconductor device). The use of a plurality of adjacent redistribution structures may be particularly useful in cases of signal routing (e.g., for HBM, or other memory devices), and may be omitted for certain embodiments. In the present embodiment, the lower layer 2650 passes VSS from the second redistribution structure 2200 to the second semiconductor die 2700 and a plurality of second TIVs 2730 disposed along an upper surface of the fourth redistribution layer 2600a.

The second TIVs 2730 may connect to electrical pads 2812 of a memory device 2800, such as through solder balls or bumps 2814. Because the first TIV's 2230 carry VCC/VSS currents at least to adequately power the first semiconductor die 2301, the second semiconductor die 2700, various transmission losses, as well as the memory device 2800, the second TIVs are less densely populated that the first TIVs. In alternate embodiments, the memory device 2800, second die 2700, etc. may be encapsulated in one or more encapsulants (not depicted by FIG. 3b), which may be applied by one or more process steps. For example, a single process step may be used to simplify device construction, whereas multiple process steps may allow for more viscous encapsulants, and avoid voids in the molding process (which may, advantageously, benefit thermal conductivity).

Referring now to FIG. 3c, the carrier substrate C2 is removed from the semiconductor device, and a plurality of first conductive terminals 2902 are formed along the first surface of the first redistribution layer, and are electrically connected to a plurality of the VSS electrical pads 2112. A plurality of second conductive terminals 2904 are formed along the first surface of the first redistribution layer, and are electrically connected to a plurality of the VCC electrical pads 2112. The semiconductor device is thereafter attached to a working substrate (e.g., a PCB assembly) C3, which comprises a plurality of conductive elements (e.g., a copper ground plane, copper power plane(s), etc.), which are disposed between insulating layers (e.g., FR-4, FR-5, etc.).

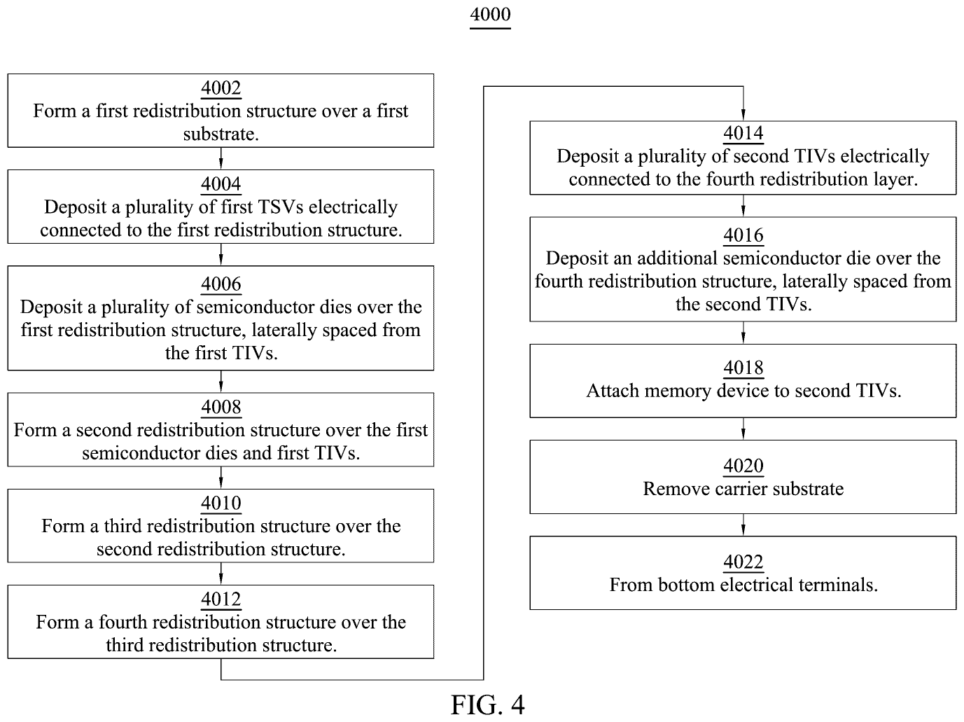

FIG. 4 includes a flowchart of an example method 4000 of fabricating a semiconductor device, in accordance with some embodiments. The method 4000 may be used to fabricate a semiconductor device having a plurality of semiconductor dies interconnected with TSVs. For example, at least some of the operations described in the method 4000 may result in the semiconductor devices depicted in FIGS. 1a-1h. The disclosed method 4000 is disclosed as a non-limiting example, and additional operations may be provided before, during, and after the method 4000 of FIG. 4. Further, some operations may only be described briefly herein, however, one skilled in the art will understand that the disclosed operations may be performed in conjunction with other disclosed methods disclosed herein, or generally known in the art. For example, one skilled in the art will understand that the evacuation of particulate matter from the environment of operation may precede the disclosed process steps, absent any explicit disclosure.

The method 4000 starts with operation 4002 wherein a first redistribution structure is formed over a first substrate. The method 4000 proceeds to operation 4004 wherein a plurality of first TIVs are electrically connected to the first redistribution structure. At operation 4006, a plurality of semiconductor dies are deposited over the first redistribution structure. At operation 4008, a second redistribution structure is formed over the first semiconductor dies and first TIVs. In turn, at operation 4010, a third redistribution structure is formed over the second redistribution structure. Operation 4012 overlays the third redistribution structure with a fourth redistribution structure. At operation 4014, a plurality of second TIVs are electrically connected to at least the fourth redistribution structure. An additional semiconductor die is placed over the fourth redistribution structure at operation 4016, and a memory device placed over the additional semiconductor device, and electrically connected to the second TIVs at operation 4018. At operation 4020, the substrate is removed, revealing a surface of the semiconductor device, so that bottom electrical terminals may be formed at operation 4022.

Referring to operation 4002, a first redistribution structure is formed over a first substrate. In an embodiment, the first redistribution structure comprises a plurality of layers, each comprising first conductive elements, which carry propagate a PDN device through the plurality of layers of the redistribution structure, and further first conductive elements, which propagate I/O through the layers of the redistribution structure. At least some of the first conductive elements are disposed along a lower (i.e., facing the carrier substrate) surface or upper surface (i.e., opposite the first surface) of the redistribution structure, to enable the connection of the first conductive elements to other elements of the semiconductor device. Operation 4002 may comprise a plurality of sub-operations. For example, sub-operation 4002a comprises selectively forming (e.g., selectively depositing) an insulating layer along a surface of the carrier substrate having openings, operation 4002b comprises adding a 3 μm thick metal layer (e.g., forming power planes, traces, etc.) along an upper surface of the insulating layer, such that the metal layer further fills the openings (i.e., the metal layer thickness may be thicker at the openings, for example, it may extend to the carrier substrate). Sub-operation 4002c comprises selectively forming an additional insulating layer (e.g., adding a layer across an entire surface of the semiconductor device and thereafter removing portions thereof to for openings). Sub-operation 4002d comprises adding an additional 3 μm thick metal layer along an upper surface of the insulating layer, such that the metal layer further fills the openings created in sub-operation 4002c. Sub-operation 4002e comprises selectively forming yet another insulating layer over the metal layer formed in operation 4002d. Finally, sub-operation 4002f comprises filling the openings created in sub-operation 4002d with metal (e.g., overlaying the surface of the semiconductor device with metal, and using a planarization process such as polishing or grinding to remove metal which may extend beyond an upper surface of the preceding insulating layer). In some embodiments, certain sub-processes may not be performed, or may be performed differently. For example, some embodiments, may not perform operation 4002f, which may allow for further elements of the semiconductor device to connect more or less directly to the metal layer formed in sub-operation 4002d.

Referring to operation 4004, a plurality of first TIVs are deposited along the first surface of the redistribution layer, (e.g., to the metal of sub-operation 4002f, and/or 4002d). In some embodiments, the first TIVs are placed into the openings from sub-operation 4002e. In some embodiments, the first TIVs may be formed similarly to the metal in 4002f.

Referring to operation 4006, a plurality of first dies are placed upon the first redistribution structure, and are laterally spaced from the first TIVs. In some embodiments in which the TIVs are grown in situ rather than placed, the first dies are placed prior to operation 4004. Thus, the formation of the insulating material (e.g., resin, polymer, oxide, etc.) which is formed to create the openings for the first TIVs may also cover one or more surface of the first dies. Alternatively, where the first TIVs are placed, a similar insulating material may also cove the first dies which may mechanically and thermally couple the first dies to additional elements of the semiconductor device. In some embodiments, an excess of insulating material covers the TIVs and/or the first dies and is removed via a planarization sub-operation. In many embodiments, the die is placed upon the first redistribution structure in conjunction with a DAF, die attach paste, etc.

Referring to operation 4008, a second redistribution structure is formed over the semiconductor die. In one embodiment, at sub-operation 4008a, openings are formed in the insulating material of operation 4006. At operation 4008b, a metal layer is formed over the insulating layer, to connect various TIVs to various die pins of the first dies. For example, PDN elements may comprise various power and ground traces and planes, and I/O elements may comprise data signals, clocks, etc. In some embodiments, the z-height of various second conductive elements such as metal structures exceeds 10 μm.

Referring to operation 4010, an third redistribution structure, which comprises third conductive elements, such as metal structures exceeding 10 μm in z-height, is formed over the third redistribution layer. Similar to various other structures of the semiconductor device, various openings may allow for connections between various layers of the semiconductor device. For example, the third redistribution structure may connect various TIVs to the semiconductor die indirectly, through the second redistribution layer. Put differently, various elements of the second redistribution layer may be connected in the third redistribution layer to couple the first dies to the first TIVs.

Referring to operation 4012, a fourth redistribution structure is formed over the third redistribution structure. The fourth redistribution structure comprises a plurality of layers of fourth conductive elements, wherein each layer of fourth conductive elements are disposed between two isolating layers, which may be formed by similar means as the various elements of the first redistribution structure. The fourth conductive elements are configured to electrically connect to at least one of the second or third conductive elements. The fourth conductive elements are also configured to comprise or connect to electrical terminals along an upper surface (i.e., facing away from the carrier substrate) which are configured to connect, through openings in the isolating layers, to an additional semiconductor die and a plurality of additional TIVs.

Referring to operation 4014, a plurality of second TIVs are placed upon the fourth redistribution structure. These second TIVs may be formed in pace, grown, or any combination thereof. In some embodiments, the z-height of the second TIVs exceeds the z-height of a contemplated additional semiconductor die, and the second TIVs are electrically connected to any of the second conductive elements, the third conductive elements and the fourth conductive elements. For example, the second TIVs may be connected to each of the second and third conductive elements (e.g., comprising connections to a PDN of the semiconductor device) by an intermediate connection with the fourth conductive element, and also be connected to a portion of the electrical terminals of the fourth redistribution structure.

Referring to operation 4016, an additional semiconductor die is placed over the fourth redistribution structure. In some embodiments, an active surface of the semiconductor die may face downward, (i.e., facing the carrier substrate) and electrically mate with the electrical terminals disposed along the surface of the fourth redistribution layer. For example, solder bumps or balls may adhere the semiconductor die with the electrical terminals of the fourth redistribution structure. In some embodiments, the fourth conductive elements electrically connect electrical terminals connected to the second TIVs and electrical terminals connected to the semiconductor device and comprise a memory bus or other connection.

Referring to operation 4018, a memory device is connected to the upper surface of the TIVs, for example, directly to the second TIVs or in conjunction with solder bumps, flux, film, paste, etc. In some embodiments, a first portion of the TIVs may connect the PDN of the semiconductor device to terminals of the memory device, and a second portion of the TIVs may connect the memory bus or other connection of the additional semiconductor die to the memory device. The memory, second additional die, and TIV's may be separated by additional encapsulants, insulating layers, etc.

Referring to operation 4020, the carrier substrate is removed from the semiconductor device by irradiating of a de-bonding surface disposed along the carrier substrate. Other embodiments may remove the carrier substrate otherwise, or may retain the carrier substrate as an intermediate substrate of the semiconductor device, which may itself be configured (e.g., balled) to interface with another substrate such as a PCB.

Referring to operation 4022, conductive terminals are electrically connected to the first conductive elements, directly, or through intermediate layers (UBM, pins, C2 balls, C4 balls, etc.). In some embodiment, the conductive terminals are configured to attach directly to a working substrate such as a PCB or rigid-flex circuit (e.g., BGA). In other embodiments, the conductive terminals may be configured to connect to a socket (e.g., land grid array, pin grid array). Still further embodiments may be configured to connect to an intermediate substrate, which may, in turn, be configured to connect to a working substrate.

In one aspect of the present disclosure, a semiconductor device is disclosed. The semiconductor device includes a semiconductor chip disposed along a first redistribution structure of conductive elements. A second redistribution structure of conductive elements is disposed along an opposite side of the first redistribution structure as the semiconductor chip. A third redistribution structure is disposed along as opposite side of the semiconductor chip as the first and second redistribution structures, and includes conductive elements of substantially lower thickness than the conductive elements of at least one of the first or second redistribution structures.

In another aspect of the present disclosure, a semiconductor device is disclosed. The semiconductor device includes a first redistribution structure having a plurality of conducive elements, a second redistribution structure disposed along a first side of the first redistribution structure and having a plurality of conductive elements, a plurality of through via structures configured to deliver a supply voltage through at least one of the first or second redistribution structures to at least two laterally spaced semiconductor chips disposed a surface of the second redistribution layer opposite the first redistribution layer.

In yet another aspect of the present disclosure, a method for fabricating a semiconductor device is disclosed. The method includes forming a first redistribution structure over a second redistribution structure, each comprising a multiple conductive elements, attaching multiple semiconductor chips and through via structures to the first redistribution structure, opposite the second redistribution structure, wherein the through via structures are laterally spaced from each of the semiconductor chips, and forming a third redistribution structure having multiple conductive elements over the plurality of semiconductor chips.

As used herein, the terms “about” and “approximately” generally mean plus or minus 10% of the stated value. For example, about 0.5 would include 0.45 and 0.55, about 10 would include 9 to 11, about 1000 would include 900 to 1100.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method for fabricating semiconductor devices, comprising:
forming a first redistribution structure over a second redistribution structure, wherein:
a first side of the first redistribution structure faces the second redistribution structure;
the first redistribution structure includes a plurality of first conductive elements and the second redistribution structure includes a plurality of second conductive elements; and
the first redistribution structure is configured to couple with a plurality of conductive terminals on a first side of the semiconductor device;
attaching a plurality of first semiconductor chips to a second side of the first redistribution structure, the second side disposed opposite to its first side and facing the second redistribution structure;
forming, between the first redistribution structure and the second redistribution structure, a plurality of through via structures on the second side of the first redistribution structure, wherein each of plurality of through via structures are laterally spaced from any of the plurality of first semiconductor chips; and
forming a third redistribution structure over the plurality of first semiconductor chips and the plurality of first through via structures, wherein the third redistribution structure includes a plurality of third conductive elements,
wherein each of the plurality of first conductive elements has a first thickness, each of the plurality of second conductive elements has a second thickness, and each of the plurality of third conductive elements has a third thickness, and wherein the third thickness is substantially less than any of the first thickness or the second thickness.

2. The method of claim 1, wherein at least one of the plurality of through via structures is configured to deliver a supply voltage, through one of the first or the second redistribution structure, to the plurality of first semiconductor chips.

3. The method of claim 1, wherein the first thickness and the second thickness are each equal to or greater than about 10 microns (μm).

4. The method of claim 1, further comprising a second semiconductor chip disposed on the second side of the first redistribution structure and laterally spaced from the first semiconductor chips.

5. The method of claim 4, wherein at least one of the plurality of first conductive elements is configured to carry at least one of a data signal or a clock signal between the first semiconductor chip and the second semiconductor chip.

6. The method of claim 1, wherein the plurality of first through via structures are each configured to couple the third redistribution structure, through at least one of the first or the second redistribution structure, to the first semiconductor chip.

7. The method of claim 1, wherein a diameter of each of the plurality of first through via structures is greater than about 1.05 times a lateral spacing between adjacent ones of the plurality of first through via structures.

8. The method of claim 1, further comprising:
forming a fourth redistribution structure disposed opposite of the second redistribution structure from the first redistribution structure; and
placing a third semiconductor chip disposed on a first side of the fourth redistribution structure opposite from a second side of the fourth redistribution structure.

9. The method of claim 8, further comprising:
forming a plurality of second through via structures laterally spaced from the third semiconductor chip.

10. The method of claim 9, wherein a first density of the plurality of first via structures is substantially greater than a second density of the plurality of second via structures.

11. The method of claim 8, further comprising coupling a fourth semiconductor chip opposite of the third semiconductor chip from the fourth redistribution structure, wherein the fourth semiconductor chip includes at least one memory device.

12. A method for fabricating semiconductor devices, comprising:
forming a first redistribution structure comprising a plurality of layers over a carrier substrate;
forming a plurality of via structures between the first redistribution structure and a second redistribution structure, wherein the plurality of via structures extend past a plurality of first semiconductor chips sandwiched between the first redistribution structure and the second redistribution structure; and
forming a third redistribution structure over the second redistribution structure, wherein conductive elements of each of the second and third redistribution structures are thicker than conductive elements of the first redistribution structure;
removing the carrier substrate; and
forming device terminals along an opposite surface of the first redistribution structure as the plurality of first semiconductor chips.

13. The method of claim 12, wherein communication and data channels between the first redistribution structure and the second redistribution structure consist of the plurality of via structures.

14. The method of claim 12, wherein one of the first redistribution structure and the second redistribution structure is a ground plane and the other of the first redistribution structure and the second redistribution structure is a power plane.

15. The method of claim 12, wherein the first plurality of chips comprise a first set of chips having an active surface facing the first redistribution structure and a second set of chips having an active surface facing the second redistribution structure.

16. The method of claim 15, wherein the second set of chips are laterally aligned with the first set of chips, and further comprising:
forming a plurality of second via structures to electrically couple the first set of chips with the first redistribution structure; and
forming a plurality of third via structures to electrically couple the second set of chips with the second redistribution structure.

17. The method of claim 16, wherein a density of the via structures is greater than a density of the second via structures.

18. A method for fabricating semiconductor devices, comprising:
forming a plurality of inter-layer via structures having first ends and second ends;
coupling the first ends with a first redistribution structure of device terminals for multi-chip semiconductor device;
coupling the second ends with:
a second redistribution structure electrically coupled with, and on a same side as, an active surface of a plurality of first semiconductor chips vertically aligned and laterally offset from each other; and
a third redistribution structure electrically coupled with, and on a same side as, an active surface of a second semiconductor chips vertically offset from the plurality of first semiconductor chips.

19. The method of claim 1, wherein the second semiconductor chip laterally extends beyond the plurality of first semiconductor chips along a first line.

20. The method of claim 1, wherein the second redistribution structure is substantially thicker than the first redistribution structure.
